(19) United States
(12) Patent Application Publication
(10) Pub. No.: US 2025/0210424 A1
(43) Pub. Date: Jun. 26, 2025

(54) SEMICONDUCTOR DEVICE AND METHOD FOR MANUFACTURING SEMICONDUCTOR DEVICE

(71) Applicant: Rohm Co., Ltd., Kyoto-shi (JP)

(72) Inventor: Kazunori FUJI, Kyoto-shi (JP)

(21) Appl. No.: 19/076,576

(22) Filed: Mar. 11, 2025

Related U.S. Application Data
(63) Continuation of application No. PCT/JP2023/030307, filed on Aug. 23, 2023.

(30) Foreign Application Priority Data
Sep. 15, 2022 (JP) 2022-147000

(51) Int. Cl. H01L 23/13; H01L 21/48; H01L 21/56; H01L 23/00; H01L 23/053; H01L 23/08; H01L 23/14; H01L 23/31; H01L 23/373; H01L 23/498; H01L 23/538; H01L 25/07; H10D 80/20

(52) U.S. Cl. CPC H01L 23/13; H01L 21/4857; H01L 21/56; H01L 23/142; H01L 23/5383; H01L 25/072; H10D 80/251; H01L 23/053; H01L 23/08; H01L 23/3121; H01L 23/3735; H01L 23/49811; H01L 23/49838; H01L 24/32; H01L 24/48; H01L 24/49; H01L 24/73; H01L 2224/32225; H01L 2224/48091; H01L 2224/48137; H01L 2224/48225; H01L 2224/49175; H01L 2224/73265; H01L 2924/10253; H01L 2924/10272; H01L 2924/13091

(57) ABSTRACT

A semiconductor device includes a support, a first semiconductor element and a second semiconductor element that are disposed on a first side in a thickness direction of the support, and a sealing body covering a part of the support and the first and the second semiconductor elements. The support includes a first surface facing a second side in the thickness direction and exposed from the sealing body, and the first surface includes an uneven region comprising a plurality of dot-shaped recesses overlapping with each other.

### TECHNICAL FIELD

The present disclosure relates to a semiconductor device and a method for manufacturing a semiconductor device.

### BACKGROUND ART

Semiconductor devices with semiconductor elements are used as power modules for constructing inverters, for example. JP-A-2018-182330 discloses an example of a conventional semiconductor device. The semiconductor device disclosed in the document includes a plurality of switching elements and a heat sink for dissipating heat from the switching elements. The heat sink is made of a metal plate, and one side of the heat sink is exposed to the outside. The one side of the heat sink is installed on an installation surface, such as on an external water-cooling jacket.

### BRIEF DESCRIPTION OF THE DRAWINGS

FIG. 1 is a perspective view of a semiconductor device according to a first embodiment of the present disclosure.

FIG. 2 is a plan view of the semiconductor device according to the first embodiment of the present disclosure.

FIG. 3 is a partial plan view of the semiconductor device according to the first embodiment of the present disclosure.

FIG. 4 is a bottom view of the semiconductor device according to the first embodiment of the present disclosure.

FIG. 5 is a sectional view taken along line V-V in FIG. 3.

FIG. 6 is a sectional view taken along line VI-VI in FIG. 3.

FIG. 7 is a circuit diagram of the semiconductor device according to the first embodiment of the present disclosure.

FIG. 8 is a partial enlarged plan view of the semiconductor device according to the first embodiment of the present disclosure.

FIG. 9 is a partial enlarged sectional view of the semiconductor device according to the first embodiment of the present disclosure.

FIG. 10 is a partial enlarged plan view showing a method for manufacturing the semiconductor device according to the first embodiment of the present disclosure.

FIG. 11 is a partial enlarged sectional view showing a method for manufacturing the semiconductor device according to the first embodiment of the present disclosure.

FIG. 12 is a bottom view showing a first variation of the semiconductor device according to the first embodiment of the present disclosure.

FIG. 13 is a bottom view showing a second variation of the semiconductor device according to the first embodiment of the present disclosure.

FIG. 14 is a bottom view showing a third variation of the semiconductor device according to the first embodiment of the present disclosure.

FIG. 15 is a bottom view showing a fourth variation of the semiconductor device according to the first embodiment of the present disclosure.

FIG. 16 is a bottom view showing a fifth variation of the semiconductor device according to the first embodiment of the present disclosure.

FIG. 17 is a sectional view of a semiconductor device according to a second embodiment of the present disclosure.

FIG. 18 is a sectional view of the semiconductor device according to the second embodiment of the present disclosure.

FIG. 19 is a perspective view of a semiconductor device according to a third embodiment of the present disclosure.

FIG. 20 is a partial plan view of the semiconductor device according to the third embodiment of the present disclosure.

FIG. 21 is a bottom view of the semiconductor device according to the third embodiment of the present disclosure.

FIG. 22 is a sectional view taken along line XXII-XXII in FIG. 20.

FIG. 23 is a sectional view taken along line XXIII-XXIII in FIG. 20.

FIG. 24 is a circuit diagram of the semiconductor device according to the third embodiment of the present disclosure.

FIG. 25 is a sectional view of a semiconductor device according to a fourth embodiment of the present disclosure.

FIG. 26 is a sectional view of the semiconductor device according to the fourth embodiment of the present disclosure.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

### First Embodiment

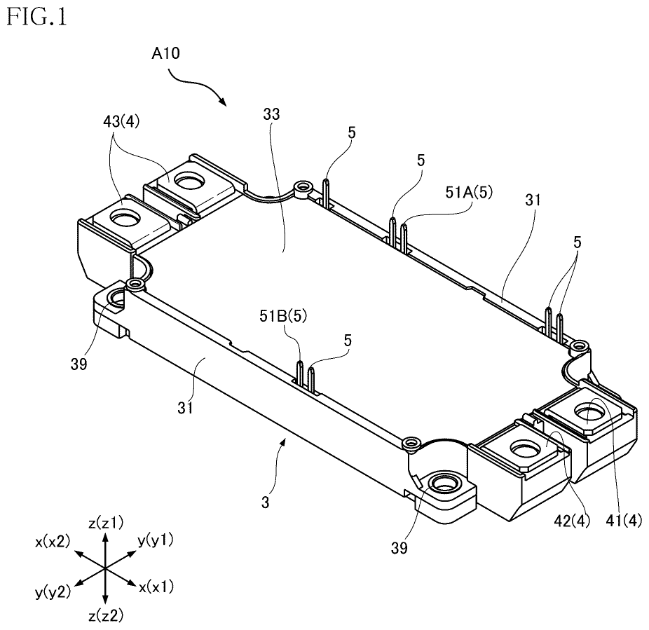

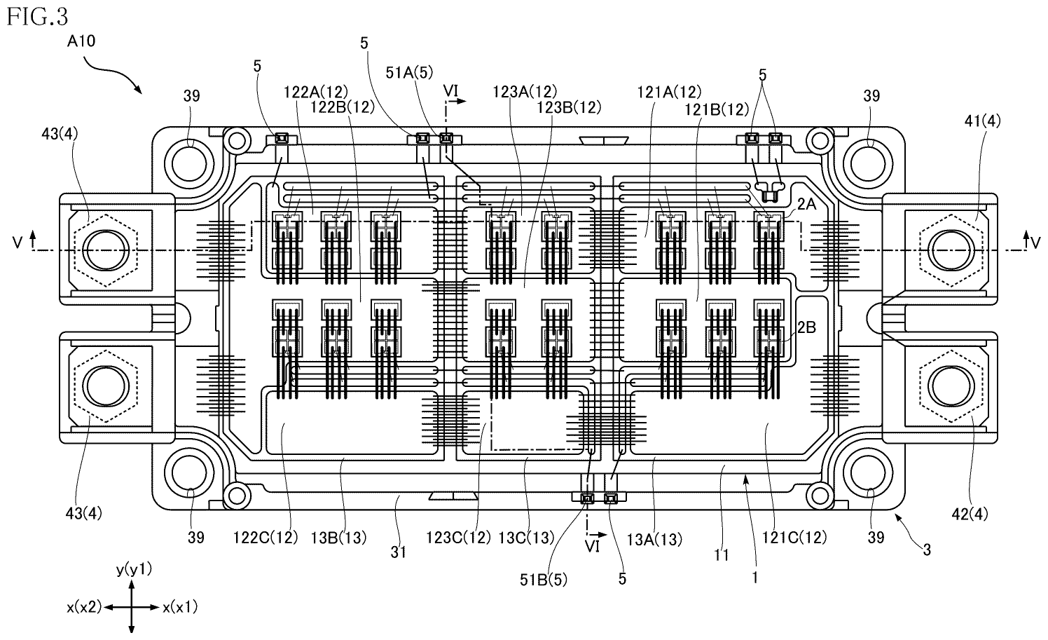

A semiconductor device A10 according to a first embodiment of the present disclosure will be described based on FIGS. 1 to 9. The semiconductor device 10 includes a support 1, a plurality of first semiconductor elements 2A, a plurality of second semiconductor elements 2B, a sealing body 3, a plurality of main current terminals 4, and a plurality of control terminals 5. For the sake of clarity, the sealing resin 32 and the cover 33, described later, are shown as transparent in FIG. 3.

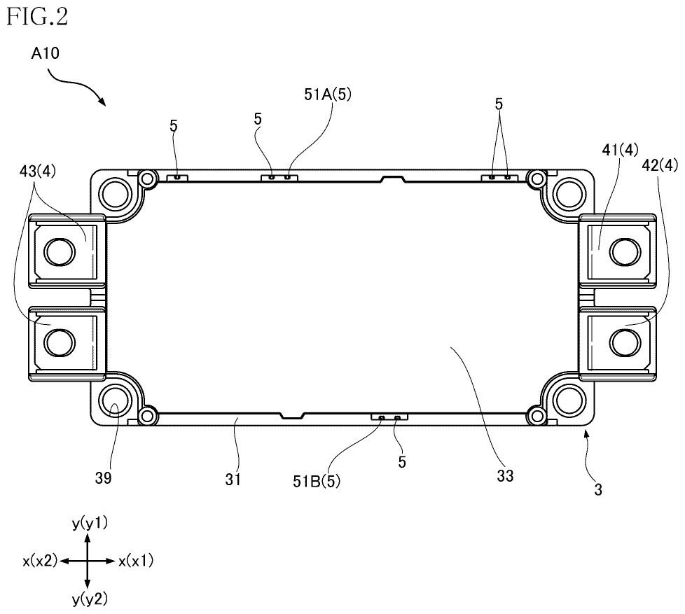

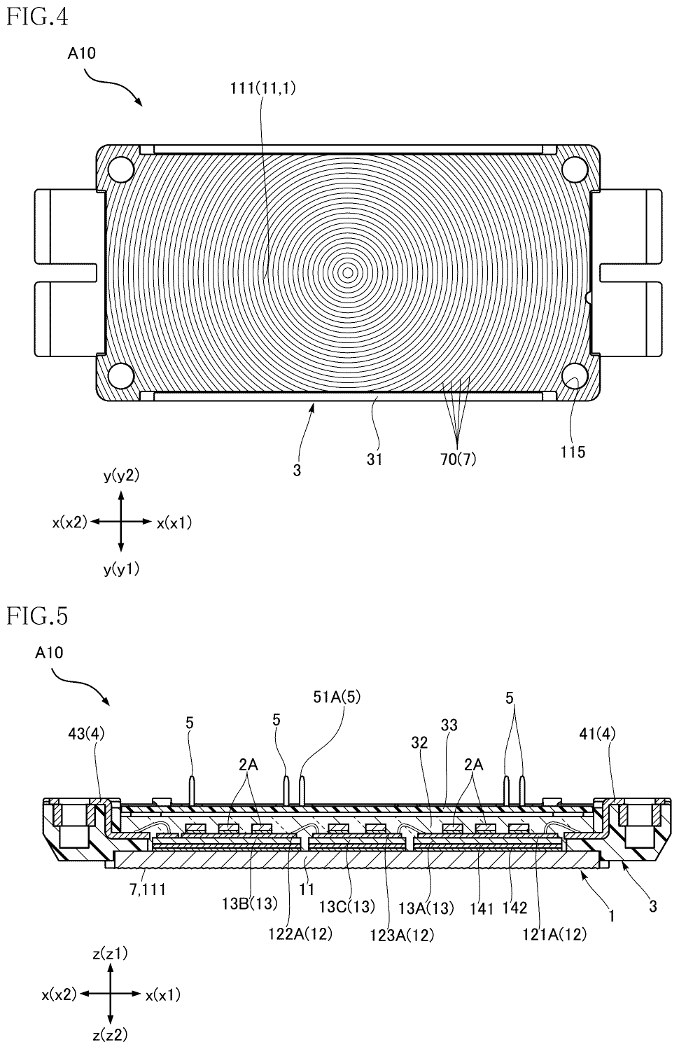

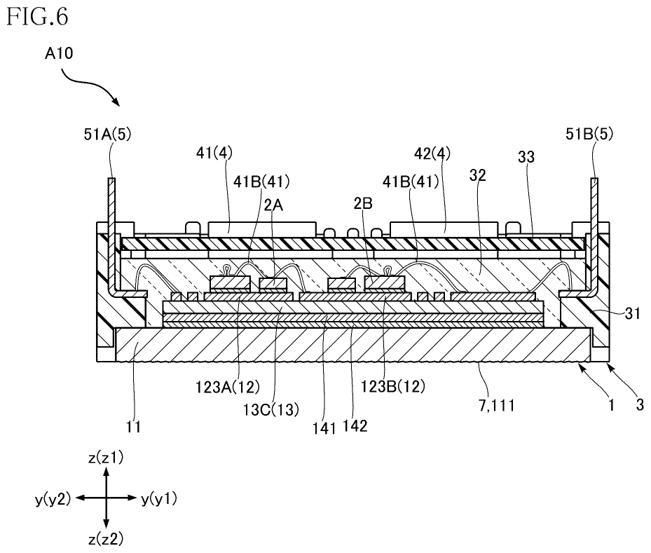

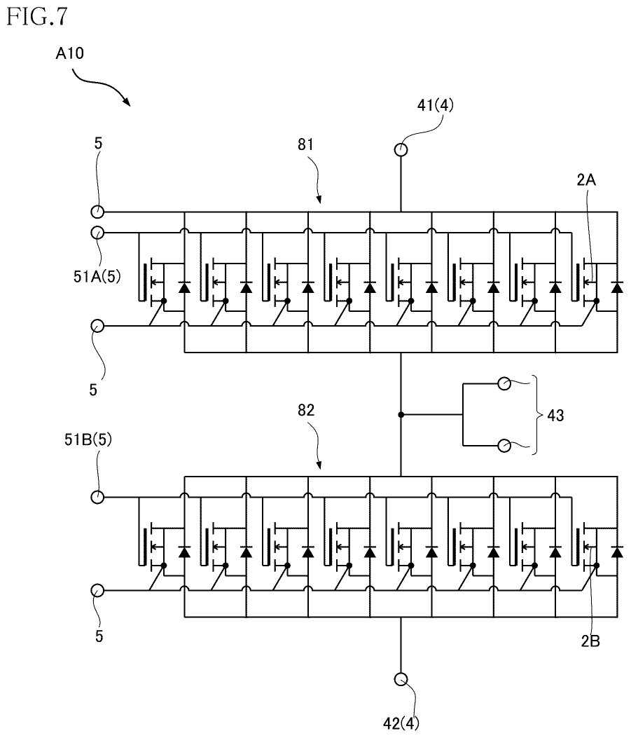

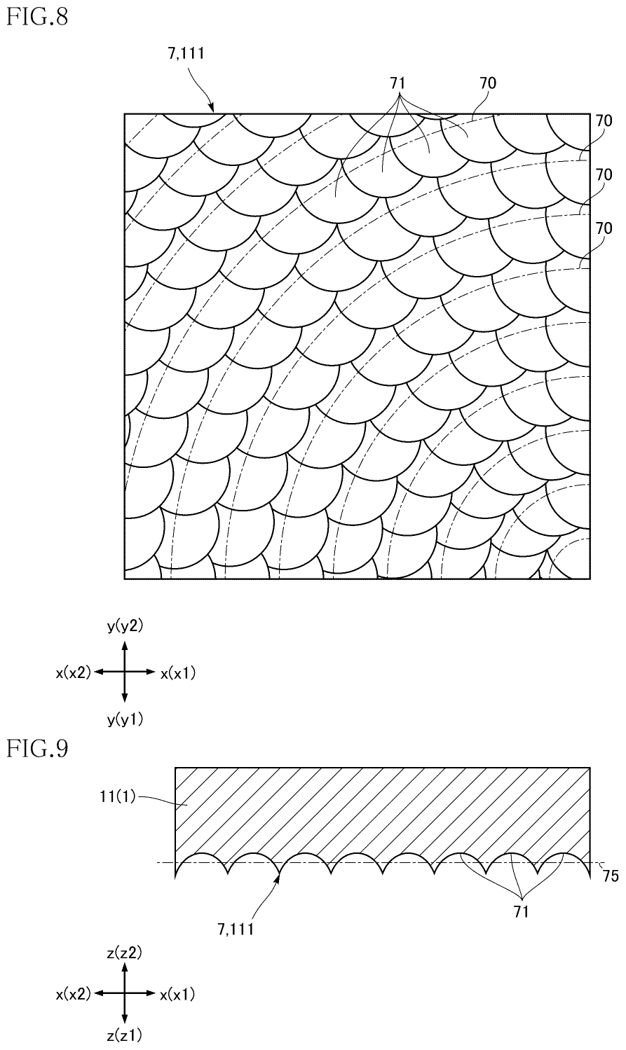

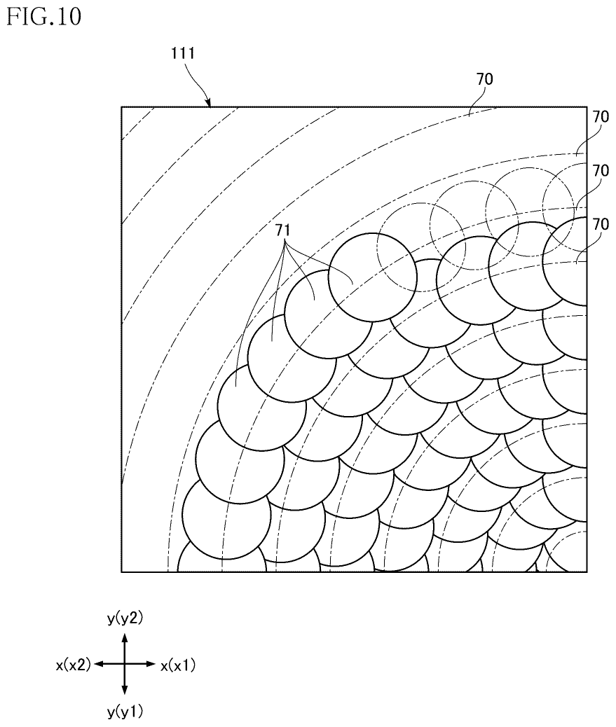

FIG. 1 is a perspective view of the semiconductor device A10. FIG. 2 is a plan view of the semiconductor device A10. FIG. 3 is a partial plan view of the semiconductor device A10. FIG. 4 is a bottom view of the semiconductor device A10. FIG. 5 is a sectional view taken along line V-V in FIG. 3. FIG. 6 is a sectional view taken along line VI-VI in FIG. 3. FIG. 7 is a circuit diagram of the semiconductor device A10. FIG. 8 is a partial enlarged plan view of the semiconductor device A10. FIG. 9 is a partial enlarged sectional view of the semiconductor device A10.

The semiconductor device 10 shown in FIG. 1 is a power module. The semiconductor device A10 is used, for example, in the inverter devices of various electrical products. As shown in FIGS. 1 and 2, the semiconductor device A10 is rectangular as viewed in the thickness direction z of the support 1. An example of a direction orthogonal to the thickness direction z is referred to as the “first direction x”. The direction orthogonal to the thickness direction z and the first direction x is referred to as the “second direction y”. The longitudinal direction of the semiconductor device A10 is the second direction y.

### Support 1

The support 1 supports the plurality of first semiconductor elements 2A and the plurality of second semiconductor elements 2B. The support 1 includes a first metal layer 11, a second metal layer 12, and an insulating layer 13. The specific configuration of the support 1 is not limited in any way. The support 1 of the present disclosure may have any configuration as long as it includes the first metal layer 11.

The first metal layer 11 is a layer mainly composed of a metal, such as Cu (copper). As shown in FIGS. 5 and 6, the first metal layer 11 has a first surface 111. The first surface 111 is exposed from the sealing body 3 to the z2 side in the z direction. Details of the first surface 111 will be described later.

The first metal layer 11 has a plurality of support holes 115. The support holes 115 are disposed at the four corners of the first metal layer 11, and each of the support holes penetrates the first metal layer 11 in the z direction.

The insulating layer 13 is disposed on the z1 side in the z direction with respect to the first metal layer 11. The insulating layer 13 is made of an insulating material, which may be mainly composed of a ceramic material such as AlN (aluminum nitride) or Al₂O₃ (alumina). In the present embodiment, the insulating layer 13 includes a first region 13A, a second region 13B, and a third region 13C. The first region 13A is positioned furthest to the x1 side in the x direction. The second region 13B is positioned furthest to the x2 side in the x direction. The third region 13C is disposed between the first region 13A and the second region 13B.

In the present embodiment, the insulating layer 13 is bonded to the first metal layer 11 via a third metal layer 141 and a bonding layer 142, as shown in FIGS. 5 and 6. The third metal layer 141 is made of a metal material, such as copper foil. The bonding layer 142 is a bonding material interposed between the first metal layer 11 and the third metal layer 141. In the semiconductor device A10, the constituent material of the bonding layer 142 is lead-free solder mainly composed of tin.

As shown in FIGS. 5 and 6, the second metal layer 12 is disposed on the z1 side in the z direction with respect to the insulating layer 13. The second metal layer 12 is in direct contact with the insulating layer 13. The second metal layer 12 is mainly composed of a metal, such as Cu (copper). The second metal layer 12 of the present embodiment includes a first region 121A, a first region 122A, a first region 123A, a second region 121B, a second region 122B, a second region 123B, a third region 121C, a third region 122C, and a third region 123C. The second metal layer 12 in the illustrated example further includes a plurality of other small regions.

The first region 121A is disposed on the x1 side in the first direction x with respect to the first region 123A. The first region 122A is disposed on the x2 side in the first direction x with respect to the first region 123A. The second region 123B is disposed on the y2 side in the second direction y with respect to the first region 123A. The second region 121B is disposed on the x1 side in the first direction x with respect to the second region 123B. The second region 122B is disposed on the x2 side in the first direction x with respect to the second region 123B. The third region 123C is disposed on the y2 side in the second direction y with respect to the second region 123B. The third region 121C is disposed on the x1 side in the first direction x with respect to the third region 123C. The third region 122C is disposed on the x2 side in the first direction x with respect to the third region 123C.

The first region 121A, the first region 122A, and the first region 123A are electrically connected to each other with a plurality of wires. The second region 121B, the second region 122B, and the second region 123B are electrically connected to each other with a plurality of wires. The third region 121C, the third region 122C, and the third region 123C are electrically connected to each other with a plurality of wires.

In the present embodiment, the second metal layer 12, the insulating layer 13, and the third metal layer 141 constitute a so-called DBC (Direct Bonding Copper) substrate. The DBC substrate and the first metal layer 11 are bonded via the bonding layer 142. Such configuration of the support 1 is an example configuration of the support of the present disclosure, and the support of the present disclosure is not limited to this.

### The Plurality of First Semiconductor Elements 2A, the Plurality of Second Semiconductor Elements 2B

The plurality of first semiconductor elements 2A and the plurality of second semiconductor elements 2B are supported on the support 1. As shown in FIG. 3, the first semiconductor elements 2A are mounted on the first region 121A, the first region 122A, and the first region 123A of the second metal layer 12. The second semiconductor elements 2B are mounted on the second region 121B, the second region 122B, and the second region 123B of the second metal layer 12.

The first semiconductor elements 2A and the second semiconductor elements 2B are MOSFETs (Metal-Oxide-Semiconductor Field-Effect Transistors) made using a semiconductor material mainly composed of SiC (silicon carbide) or Si (silicon), for example. The first semiconductor elements 2A and the second semiconductor elements 2B are not limited to MOSFETs and may be IGBTs (Insulated Gate Bipolar Transistors). In the description of the semiconductor device A10, the first semiconductor elements 2A and the second semiconductor elements 2B are n-channel type MOSFETs made using a semiconductor material mainly composed of SiC (silicon carbide). In present embodiment, a protective element such as a diode is connected to each of the first and the second semiconductor elements 2A and 2B.

The drain electrodes of the first semiconductor elements 2A are conductively bonded to the first region 121A, the first region 122A, and the first region 123A of the second metal layer 12. The drain electrodes of the second semiconductor elements 2B are conductively bonded to the second region 121B, the second region 122B, and the second region 123B of the second metal layer 12. The source electrodes of the first semiconductor elements 2A are electrically connected to the first region 122A, the second region 122B, and the second region 123B with a plurality of wires. The source electrodes of the second semiconductor elements 2B are electrically connected to the third region 121C, the third region 122C, and the third region 123C with a plurality of wires.

### Sealing Body 3

The sealing body 3 seals and protects the first semiconductor elements 2A and the second semiconductor elements 2B. The specific configuration of the sealing body 3 is not limited in any way. In the present embodiment, the sealing body 3 includes a case 31, a sealing resin 32, and a cover 33.

The case 31 is an electrically insulating member surrounding the first semiconductor elements 2A, the second semiconductor elements 2B, and the second metal layer 12 as viewed in the thickness direction z, as shown in FIG. 3. The case 31 may have a frame-like shape. The case 31 is made mainly from a synthetic resin that has electrical insulation properties and excellent heat resistance, such as PPS (polyphenylene sulfide).

The case 31 of the present embodiment has a plurality of mounting holes 39. The positions of the mounting holes 39 correspond to the positions of the support holes 115 provided in the first metal layer 11. The mounting holes 39 and the support holes 115 are used to attach the semiconductor device A10 to, for example, a heat sink (not shown).

The sealing resin 32 is contained in the area surrounded by the support 1 and the case 31, as shown in FIGS. 5 and 6. The sealing resin 32 covers the first semiconductor elements 2A and the second semiconductor elements 2B. Preferably, the sealing resin 32 is a synthetic resin that is excellent in heat resistance and adhesion and also has electrical insulation properties. The sealing resin 32 is, for example, silicone gel mainly composed of thermosetting organopolysiloxane.

As shown in FIGS. 2, 5 and 6, the cover 33 closes the internal area of the semiconductor device A10 that is defined by the support 1 and the case 31 from the z1 side in the z direction. The cover 33 is made of a synthetic resin having electrical insulation properties.

### The Plurality of Main Current Terminals 4

The plurality of main current terminals 4 are terminals through which the main current, which is switched by the semiconductor device A10, is input and output. In the present embodiment, the plurality of main current terminals 4 include a first power supply terminal 41, a second power supply terminal 42, and two output terminals 43, as shown in FIGS. 1 to 3, 5 and 6.

The first power supply terminal 41 is disposed on the x1 side in the first direction x and electrically connected to the first region 121A with a plurality of wires. Thus, the first power supply terminal 41 is electrically connected to the drain electrodes of the first semiconductor elements 2A.

The second power supply terminal 42 is disposed on the x1 side in the first direction x and disposed on the y2 side in the second direction y with respect to the first power supply terminal 41. The second power supply terminal 42 is electrically connected to the third region 121C with a plurality of wires. Thus, the second power supply terminal 42 is electrically connected to the source electrodes of the second semiconductor elements 2B.

The two output terminals 43 are disposed on the x2 side in the first direction x. The two output terminals 43 are electrically connected to the second region 122B with a plurality of wires. Thus, the two output terminals 43 are electrically connected to the source electrodes of the first semiconductor elements 2A and the drain electrodes of the second semiconductor elements 2B.

### The Plurality of Control Terminals 5

The plurality of control terminals 5 are terminals through which signals such as control signals and detection signals for operating the semiconductor device A10 are input and output. As shown in FIGS. 1 and 3, the control terminals 5 are disposed on opposite sides in the second direction y of the case 31 of the sealing body 3 and protrude to the z1 side in the z direction.

The plurality of control terminals 5 include a first gate terminal 51A and a second gate terminal 51B. The first gate terminal 51A is electrically connected to the gate electrodes of the first semiconductor elements 2A. The second gate terminal 51B is electrically connected to the gate electrodes of the second semiconductor elements 2B. Other control terminals 5 are used, for example, as a source sense terminal, a temperature monitoring terminal, a current monitoring terminal, or a voltage monitoring terminal, as appropriate.

FIG. 7 shows the circuit configuration of the semiconductor device A10. The semiconductor device A10 has a half-bridge circuit that includes an upper arm circuit 81 and a lower arm circuit 82. The upper arm circuit 81 is constituted of the first region 121A, the first region 122A and the first region 123A, and the plurality of first semiconductor elements 2A electrically bonded to these. The first semiconductor elements 2A are connected in parallel between the first power supply terminal 41 and the output terminal 43. The gate electrodes of the first semiconductor elements 2A in the upper arm circuit 81 are connected in parallel to the first gate terminal 51A. The first semiconductor elements 2A in the upper arm circuit 81 are driven simultaneously by applying a gate voltage to the first gate terminal 51A using a drive circuit, such as a gate driver, disposed outside the semiconductor device A10.

The lower arm circuit 82 is constituted of the second region 121B, the second region 122B and the second region 123B, and the plurality of second semiconductor elements 2B electrically bonded to these. The second semiconductor elements 2B are connected in parallel between the output terminal 43 and the second power supply terminal 42. The gate electrodes of the second semiconductor elements 2B in the lower arm circuit 82 are connected in parallel to the second gate terminal 51B. The second semiconductor elements 2B in the lower arm circuit 82 are driven simultaneously by applying a gate voltage to the second gate terminal 51B using a drive circuit, such as a gate driver, disposed outside the semiconductor device A10.

### Uneven Region 7

As shown in FIGS. 4, 8 and 9, the first surface 111 of the first metal layer 11 has an uneven region 7. The first surface 111 may include the uneven region 7 and other regions, or the uneven region 7 may be provided entirely on the first surface 111. In the illustrated example, the uneven region 7 is provided entirely on the first surface 111.

The uneven region 7 is formed of a plurality of dot-shaped recesses 71 overlapping with each other. As shown in FIGS. 8 and 9, adjacent recesses 71 are arranged so as to partially overlap with each other. The plurality of recesses 71 are arranged along a plurality of arrangement lines 70. For convenience, the arrangement lines 70 are shown as lines connecting the centers of the recesses as viewed in the thickness direction z.

The shape, size and arrangement of the arrangement lines 70 are not limited in any way. In the illustrated example, the plurality of arrangement lines 70 are a plurality of curves having different radii of curvature. The arrangement lines 70 are arranged concentrically. In the illustrated example, the arrangement lines 70 form circles.

The average line 75 shown in FIG. 9 is a line obtained by averaging the shape lines of the recesses 71. In the present embodiment, the average line 75 is along a plane that contains the first direction x and the second direction y.

The size of each recess 71 is not limited in any way. As an example of the size of the recesses 71, the depth in the thickness direction z may be 0.5 μm or more and 10 μm or less. Also, the pitch of the arrangement lines 70 is not limited in any way. As an example, the pitch of the arrangement lines 70 may be 10 μm or more and 200 μm or less.

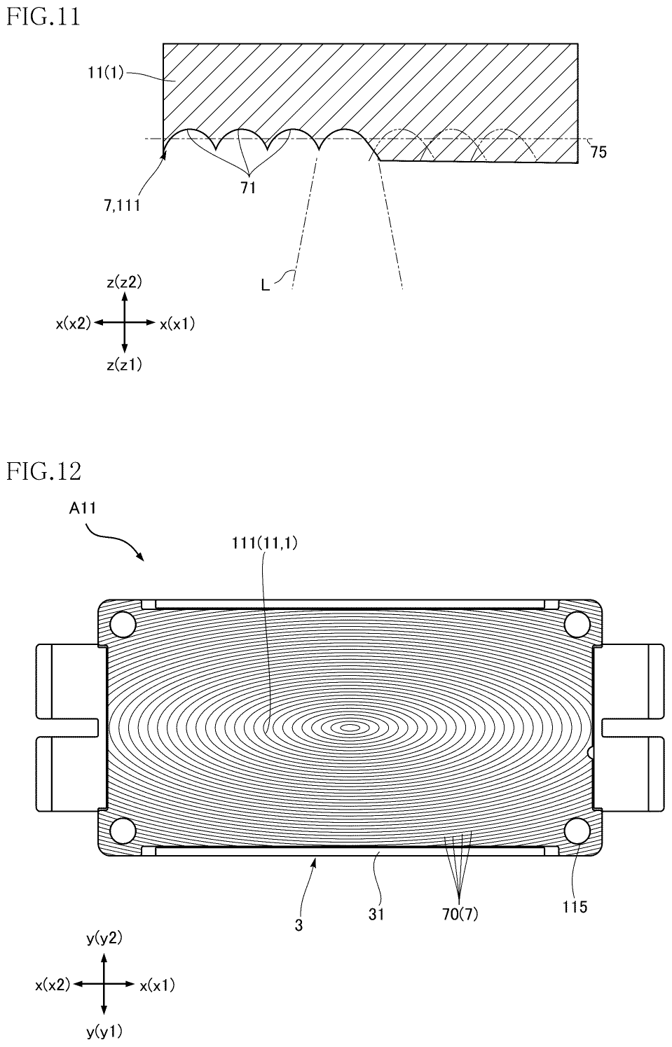

FIGS. 10 and 11 show the step of forming the uneven region 7 in the first surface 111 in the method for manufacturing the semiconductor device A10. In this step, the plurality of recesses 71 are formed by irradiating the first surface 111 with a pulsed laser L.

As the pulsed laser L, one that can form desired recesses 71 in the first surface 111 is selected as appropriate. When the first metal layer 11 is mainly composed of Cu (copper), a UV-A (long-wave ultraviolet) laser having a wavelength of 380 to 320 nm or a green laser having a wavelength of 560 to 500 nm may be used as the pulse laser L, with the wavelength set to 355 nm or 532 nm, for example.

For example, the optical system that emits the pulsed laser L is controlled to direct the pulsed laser L along the plurality of arrangement lines 70. As a result, the plurality of recesses 71 are sequentially formed in the first surface 111. In the illustrated example, the distance between the centers of adjacent recesses 71 is smaller than the size of a recess 71 formed by one pulse of the laser L. Thus, adjacent recesses 71 are formed sequentially so as to overlap with each other. By continuing such irradiation of the pulsed laser L, the uneven region 7 is formed in the first surface 111.

Next, the effects of the semiconductor device A10 and the manufacturing method of the semiconductor device A10 will be described.

When the semiconductor device A10 is used, for example, as a power module that constitutes an inverter in a vehicle, the semiconductor device is installed with the first surface 111 facing an installation surface, such as on a water-cooling jacket or a heat sink. A paste-like material such as thermal compound is placed between the first surface and the installation surface. The temperature rises and falls during operation of the semiconductor device A10. There may be a concern that due to a difference in thermal expansion between the first metal layer 11 and the water-cooling jacket, the heat sink, or the like, the thermal compound may be pushed outward and leak from between the first surface 111 and the installation surface. According to the present embodiment, the first surface 111 of the support 1 has the uneven region 7 as shown in FIGS. 4, 8, and 9. The uneven region 7 is formed of a plurality of dot-shaped recesses 71 adjacent to each other. This suppresses the material, such as thermal compound, provided by the first surface 111 from leaking to the outside.

As shown in FIGS. 10 and 11, the plurality of recesses 71 are formed by irradiating the first surface 111 with a pulsed laser L. This makes it possible to form recesses 71 having a desired depth and size in a desired area at a desired arrangement density.

The plurality of recesses 71 are arranged along the plurality of arrangement lines 70. This prevents the arrangement density of the recesses 71 from becoming excessively uneven.

The plurality of arrangement lines 70 include a plurality of curves having different radii of curvature. In the present embodiment, the arrangement lines 70 form a plurality of circles arranged concentrically. This allows the plurality of recesses 71 to be arranged further evenly from the center of the concentric arrangement toward the outside.

The manufacturing method using the pulsed laser L is suitable for forming the recesses 71 along a plurality of arrangement lines 70 that are curves with different radii of curvature. For example, if the uneven region 7 formed of a plurality of recesses 71 is to be formed by machine cutting, it is very difficult to form the recesses 71 along concentric arrangement lines 70.

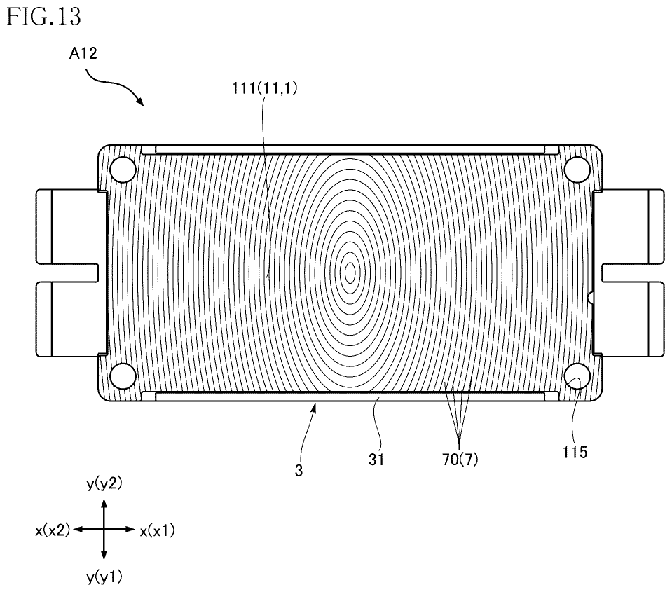

FIGS. 12 to 26 show other embodiments of the present disclosure. In these figures, the elements that are identical or similar to those of the foregoing embodiment are denoted by the same reference signs as those used for the foregoing embodiment. Various parts of variations and embodiments may be selectively used in any appropriate combination as long as it is technically compatible.

### First Embodiment, First Variation

FIG. 12 shows a first variation of the semiconductor device A10. The semiconductor device A11 of the present variation differs from the semiconductor device A10 described above in shape of the plurality of arrangement lines 70 of the uneven region 7. In the present variation, the plurality of arrangement lines 70 form ellipses whose major axis direction corresponds to the first direction x and minor axis direction corresponds to the second direction y. The arrangement lines 70 are arranged concentrically.

The present variation also suppresses the leakage of the material interposed between the first surface 111 and the installation surface. As understood from the present variation, the concentric arrangement of the arrangement lines 70 is not limited to the arrangement in which the arrangement lines 70 form circles. Also, the plurality of arrangement lines 70 may be configured to form both circles and ellipses.

### First Embodiment, Second Variation

FIG. 13 shows a second variation of the semiconductor device A10. In the semiconductor device A12 of the present variation, the plurality of arrangement lines 70 form ellipses that are arranged concentrically. Specifically, the arrangement lines 70 form ellipses whose major axis direction corresponds to the second direction y and minor axis direction corresponds to the first direction x. That is, the minor axis direction of the arrangement lines 70 corresponds to the longitudinal direction of the first surface 111.

The present variation also suppresses the leakage of the material interposed between the first surface 111 and the installation surface. As understood from the present variation, when the arrangement lines 70 form ellipses, the major axis direction and the minor axis direction are not limited in any way. For the arrangement lines 70 of the present variation, the pitch in the first direction x, which is the minor axis direction, is smaller than the pitch in the second direction y, which is the major axis direction. This makes it possible to set the pitch of the arrangement lines 70 in the first direction x, which is the longitudinal direction of the first surface 111, to be smaller. Therefore, the present variation is suitable for suppressing leakage in the first direction x of the material, such as thermal compound, by the installation surface.

### First Embodiment, Third Variation

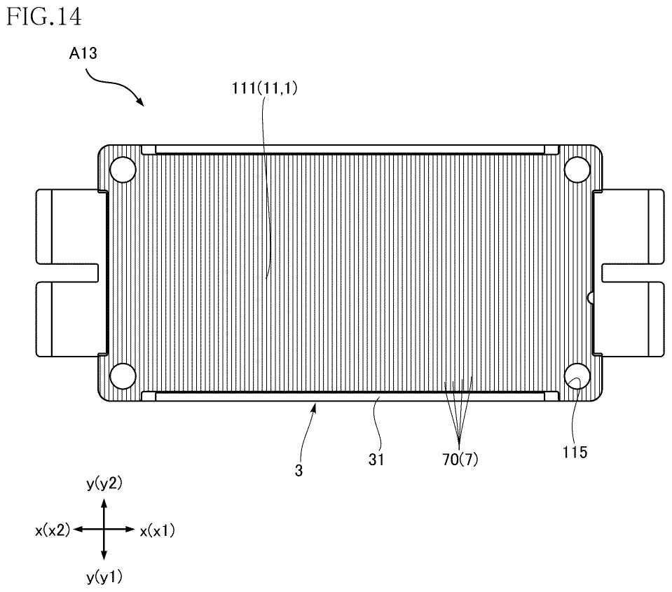

FIG. 14 shows a third variation of the semiconductor device A10. In the semiconductor device A13 of the present variation, the plurality of arrangement lines 70 are straight lines. In the present variation, the arrangement lines 70 extend along the second direction y, which is the short-side direction of the first surface 111.

The present variation also suppresses the leakage of the material interposed between the first surface 111 and the installation surface. As understood from the present variation, the arrangement lines 70 may be curved or straight. In the case where the arrangement lines 70 are straight lines, the direction along which the straight lines extend is not limited in any way. In the present variation, the arrangement lines 70 are straight lines extending along the second direction y, which is the short-side direction of the first surface 111, and arranged side by side in the first direction x, which is the longitudinal direction of the first surface 111. This is suitable for suppressing leakage in the first direction x of the material, such as thermal compound, by the installation surface.

### First Embodiment, Fourth Variation

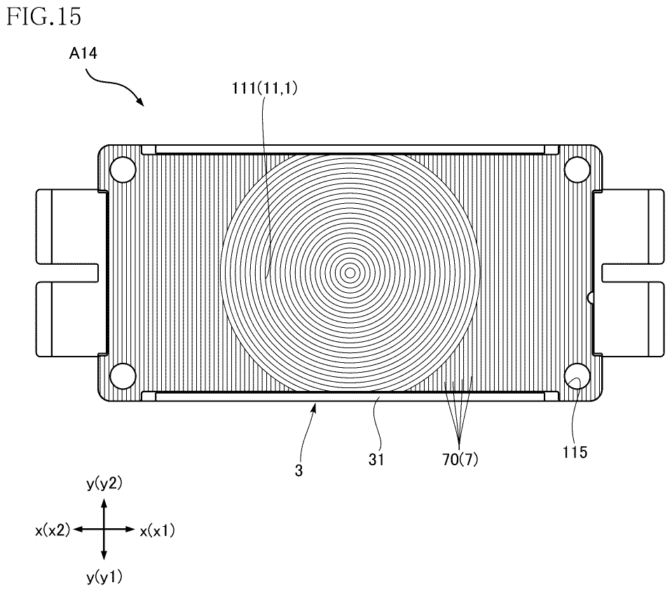

FIG. 15 shows a fourth variation of the semiconductor device A10. In the semiconductor device A14 of the present variation, the plurality of arrangement lines 70 include curved lines and straight lines. Specifically, the arrangement lines 70 include a plurality of concentric circles. The arrangement lines 70 also include a plurality of straight lines disposed on opposite sides of the circles in the first direction x. The straight lines extend along the second direction y and are arranged side by side in the first direction x.

The present variation also suppresses the leakage of the material interposed between the first surface 111 and the installation surface. As understood from the present variation, the plurality of arrangement lines 70 may include curved lines and straight lines. The provision of the arrangement lines 70 that are straight lines extending along the second direction y on opposite sides in the first direction x, which is the longitudinal direction of the first surface 111, suppresses leakage in the first direction x of the material, such as thermal compound, by the installation surface.

### First Embodiment, Fifth Variation

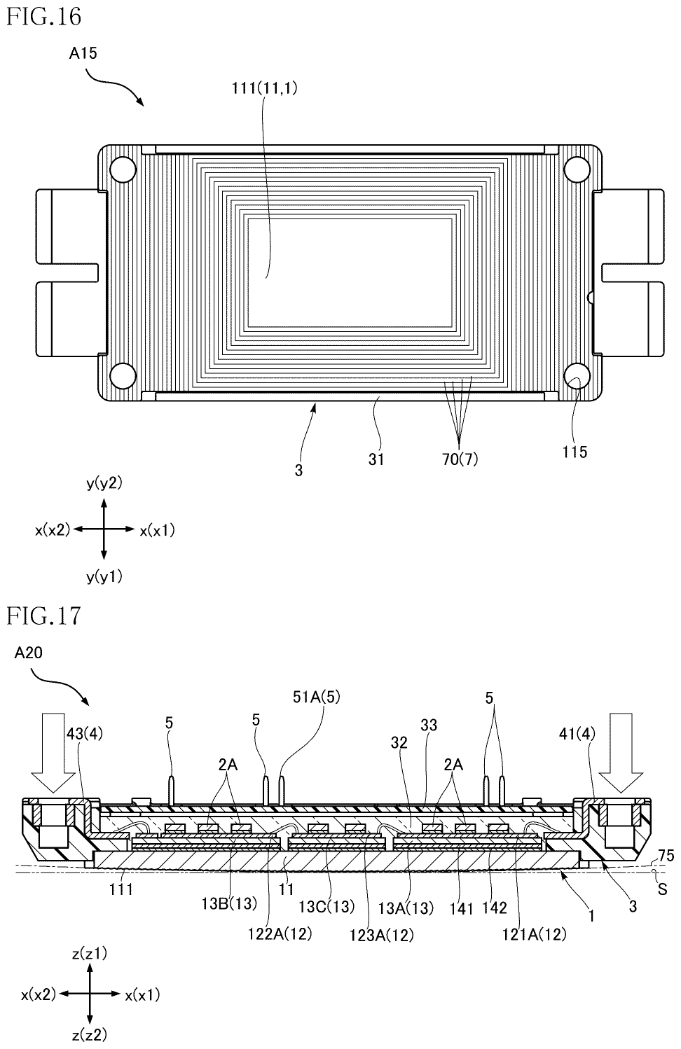

FIG. 16 shows a fifth variation of the semiconductor device A10. The semiconductor device A15 of the present variation has an uneven region 7 in a portion of the first surface 111. The uneven region 7 of the present variation has the shape of a loop as viewed in the thickness direction z, and more specifically, has the shape of a rectangular loop elongated in the first direction x. Inside the uneven region 7 is provided a flat surface region where no recesses 71 are formed.

The present variation also suppresses the leakage of the material interposed between the first surface 111 and the installation surface. As understood from the present variation, the uneven region 7 may be provided only at a portion of the first surface 111. The provision of the uneven region 7 at the periphery of the first surface 111 suppresses leakage of the above-described material, such as thermal compound, from the periphery of the first surface 111.

### Second Embodiment

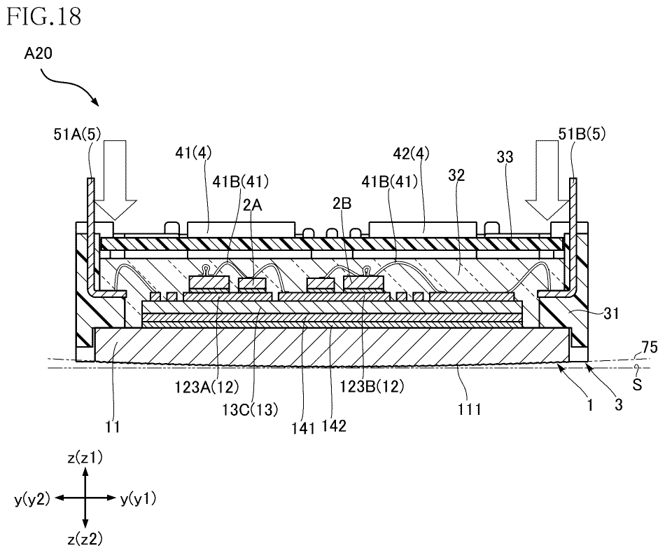

FIGS. 17 and 18 show a semiconductor device according to a second embodiment of the present disclosure. In the semiconductor device A20 of the present embodiment, the average line 75 of the uneven region 7 in the first surface 111 bulges to the z2 side in the thickness direction z. The size of the bulging shape of the uneven region 7 as viewed in the thickness direction z is not limited in any way. For example, the size of the bulging shape as viewed in the thickness direction z is set to ⅓ or more of the size of the first surface 111 in the short-side direction.

The uneven region 7, of which average line 75 bulges to the z2 side in the thickness direction z, can be formed, for example, by setting the irradiation power or irradiation time of the pulsed laser L for forming the recesses 71 to be smaller or shorter at a location closer to the center of the first surface 111 and larger or longer at a location farther from the center.

The present variation also suppresses the leakage of the material interposed between the first surface 111 and the installation surface. The semiconductor device A20 is installed on the installation surface S shown in FIGS. 17 and 18 by inserting bolts or the like through the plurality of support holes 115. Because of the shape of the average line 75 of the uneven region 7 that bulges to the z2 side in the thickness direction z, the central portion of the first surface 111 first comes into contact with the installation surface S during the installation process. At that time, the four corners of the first surface 111 are relatively spaced apart from the installation surface S. When the fastening force of the above-described bolts or the like is subsequently increased, a moment is generated that bends the first metal layer 11 from the four corners to the z2 side in the thickness direction z. As a result, the four corners of the first surface 111 are brought closer to the installation surface S. Thus, the entirety of the first surface 111 can be reliably brought into contact with or closer to the installation surface S.

### Third Embodiment

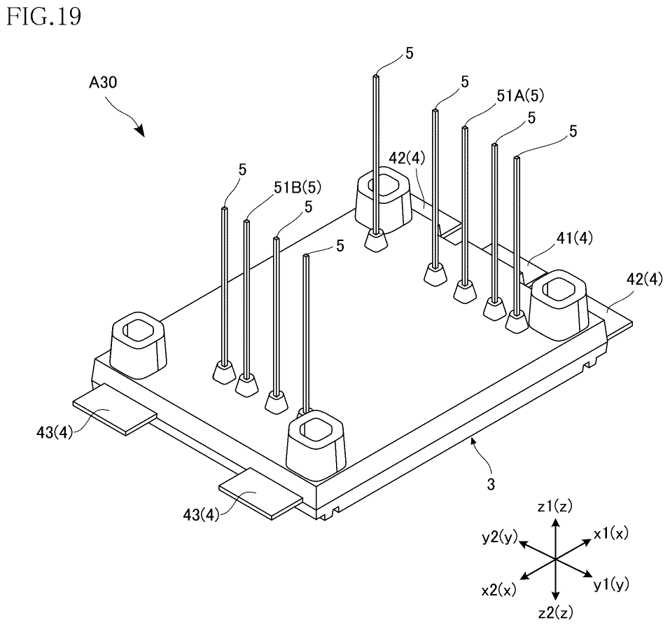

FIGS. 19 to 24 show a semiconductor device according to a third embodiment of the present disclosure. The semiconductor device A30 of the present embodiment includes a support 1, a plurality of first semiconductor elements 2A, a plurality of second semiconductor elements 2B, a sealing body 3, a plurality of main current terminals 4, a plurality of control terminals 5, a first conductive member 61, and a second conductive member 62.

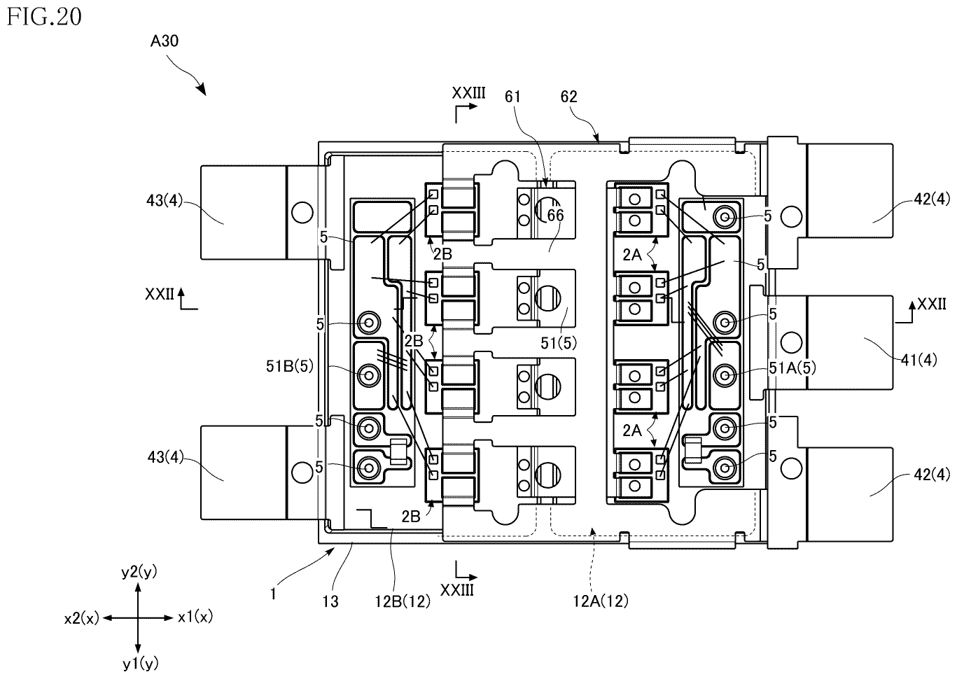

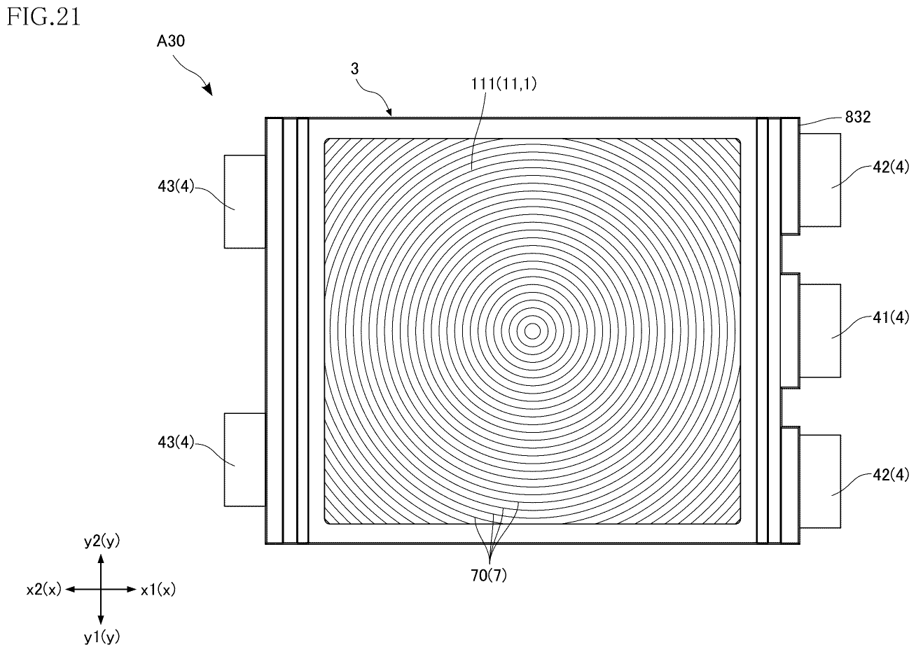

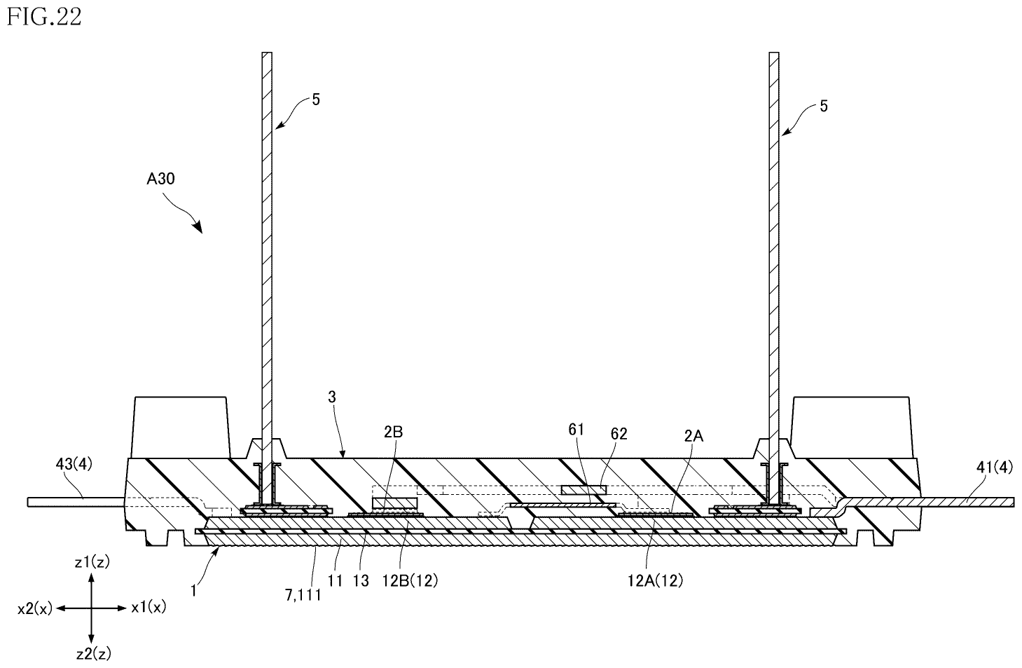

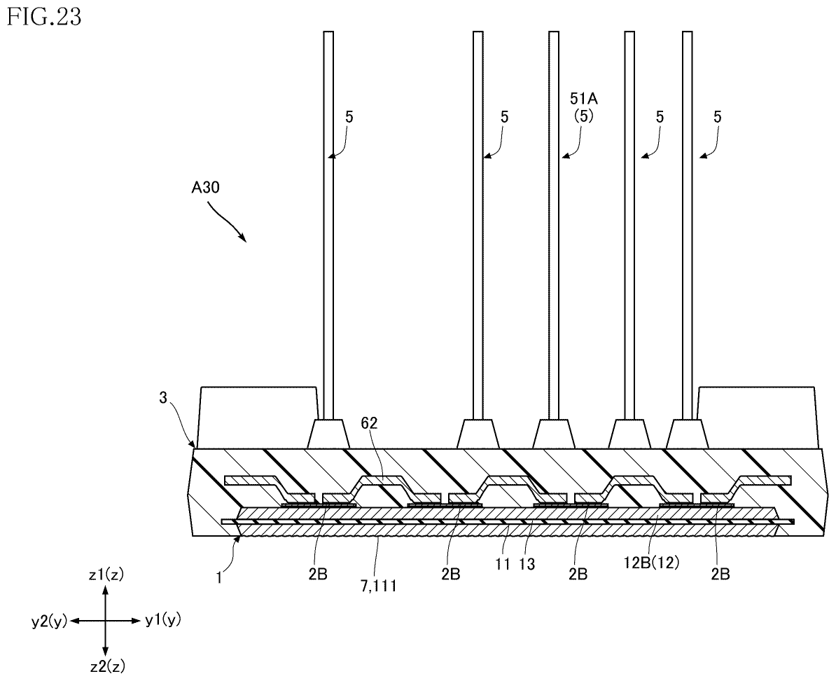

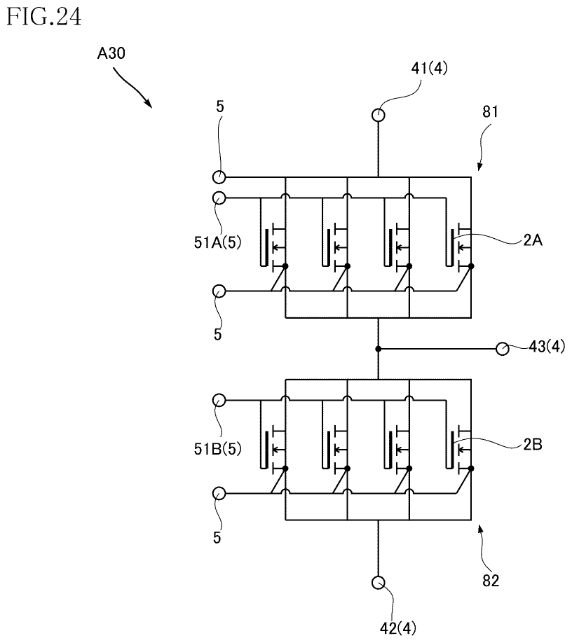

FIG. 19 is a perspective view of the semiconductor device A30. FIG. 20 is a schematic plan view of the semiconductor device A30. FIG. 21 is a bottom view of the semiconductor device A30. FIG. 22 is a sectional view taken along line XXII-XXII in FIG. 20. FIG. 23 is a sectional view taken along line XXIII-XXIII in FIG. 20. FIG. 24 is a circuit diagram of the semiconductor device A30.

### Support 1

The support 1 supports the plurality of first semiconductor elements 2A and the plurality of second semiconductor elements 2B. The support 1 is not limited to any specific configuration, and is provided by a DBC (Direct Bonding Copper) substrate or an AMB (Active Metal Brazing) substrate in the present embodiment. The support 1 includes an insulating layer 13, a second metal layer 12, and a first metal layer 11. The second metal layer 12 includes a first region 12A and a second region 12B. The dimension of the support 1 in the thickness direction z is, for example, 0.4 mm or more and 3.0 mm or less.

The first metal layer 11 is formed on the lower surface (the surface facing the z2 side in the thickness direction z) of the insulating layer 13. The constituent material of the first metal layer 11 includes, for example, Cu (copper). The first metal layer 11 has a first surface 111. The first surface 111 is a flat surface facing the z2 side in the thickness direction z. As shown in FIGS. 21, 22, and 23, the first surface 111 is exposed from the sealing body 3. The first metal layer 11 overlaps with both the first region 12A and the second region 12B in plan view.

In the present embodiment again, the first surface 111 has an uneven region 7. The specific configuration of the uneven region 7 can be set to various configurations, including the configurations of the above-described embodiment and the variations.

The insulating layer 13 may be mainly made of a ceramic material having excellent thermal conductivity. Examples of such a ceramic material include SiN (silicon nitride). The insulating layer 13 is not limited to a ceramic material, and may be an insulating resin sheet, for example. The insulating layer 13 is, for example, rectangular in plan view. The dimension of the insulating layer 13 in the thickness direction z is, for example, 0.05 mm or more and 1.0 mm or less.

The second metal layer 12 is formed on the z1 side of the insulating layer 13 in the z direction. The constituent material of the second metal layer 12 includes, for example, Cu (copper). The constituent material may include, for example, Al (aluminum) instead of Cu (copper). The dimension of the second metal layer 12 in the thickness direction z is, for example, 0.1 mm or more and 1.5 mm or less.

The second metal layer 12 of the present embodiment has a first region 12A and a second region 12B. The first region 12A and the second region 12B are spaced apart from each other in the first direction x. The first region 12A is located on the x1 side of the second region 12B in the first direction x. Each of the first region 12A and the second region 12B is, for example, rectangular in plan view. The first region 12A and the second region 12B, together with the first conductive member 61 and the second conductive member 62, form a path for the main circuit current switched by the first semiconductor elements 2A and the second semiconductor elements 2B.

### The Plurality of First Semiconductor Elements 2A, the Plurality of Second Semiconductor Elements 2B

The first semiconductor elements 2A and the second semiconductor elements 2B are the core components for the functions of the semiconductor device A30. The constituent material of the first semiconductor elements 2A and the second semiconductor elements 2B is a semiconductor material mainly composed of SiC (silicon carbide), for example. The semiconductor material is not limited to SiC, and may be Si (silicon), GaN (gallium nitride), or C (diamond), for example. Each of the first and the second semiconductor elements 2A and 2B is, for example, a power semiconductor chip having a switching function, such as a MOSFET (Metal Oxide Semiconductor Field Effect Transistor).

The first semiconductor elements 2A and the second semiconductor elements 2B are MOSFETs in the present embodiment, but the present disclosure is not limited to this. The first semiconductor elements 2A and the second semiconductor element 2B may be other transistors such as IGBTs (Insulated Gate Bipolar Transistors). The first and the second semiconductor element 2A and 2B are all identical with each other. The first semiconductor elements 2A and the second semiconductor element 2B are, for example, n-channel MOSFETs, but they may be p-channel MOSFETs.

The drain electrodes of the first semiconductor elements 2A are conductively bonded to the first region 12A. The drain electrodes of the second semiconductor elements 2B are conductively bonded to the second region 12B.

### Sealing Body 3

The sealing body 3 covers the first semiconductor elements 2A, the second semiconductor elements 2B, the support 1 (excluding the first surface 111), a part of each main current terminal 4, a part of each control terminal 5, the first conductive member 61, and the second conductive member 62. The sealing body 3 of present embodiment is made of black epoxy resin, for example. The sealing body 3 is formed by molding, for example. The sealing body 3 has a dimension of about 35 mm to 60 mm in the first direction x, a dimension of about 35 mm to 50 mm in the second direction y, and a dimension of about 4 mm to 15 mm in the thickness direction z. These dimensions are the sizes of the largest portions along each direction.

### The Plurality of Main Current Terminals 4

The plurality of main current terminals 4 are terminals through which the main current, which is switched by the semiconductor device A30, is input and output. In the present embodiment, the plurality of main current terminals 4 include a first power supply terminal 41, two second power supply terminals 42, and two output terminals 43. Each of the main current terminals 4 is made of a metal plate. The metal plate contains, for example, Cu (copper) or a Cu (copper) alloy.

The first power supply terminal 41 is disposed on the x1 side in the first direction x. The first power supply terminal 41 is conductively bonded to the first region 12A. Thus, the first power supply terminal 41 is electrically connected to the drain electrodes of the first semiconductor elements 2A.

The two second power supply terminals 42 are disposed on the x1 side in the first direction x and on opposite sides of the first power supply terminal 41 in the second direction y. The two second power supply terminals 42 are electrically connected to the source electrodes of the second semiconductor elements 2B via the second conductive member 62. The second conductive member 62 is made of, for example, a metal plate. The metal plate contains, for example, Cu (copper) or a Cu (copper) alloy. The second conductive member 62 may be formed integrally with the two second power supply terminals 42.

The two output terminals 43 are disposed on the x2 side in the first direction x. The two output terminals 43 are electrically connected to the second region 12B. The second region 12B is also electrically connected to the source electrodes of the first semiconductor elements 2A via the first conductive member 61. Thus, the two output terminals 43 are electrically connected to the source electrodes of the first semiconductor elements 2A and the drain electrodes of the second semiconductor elements 2B. The first conductive member 61 is made of, for example, a metal plate. The metal plate contains, for example, Cu (copper) or a Cu (copper) alloy.

### The Plurality of Control Terminals 5

The plurality of control terminals 5 are terminals through which signals such as control signals and detection signals for operating the semiconductor device A30 are input and output. As shown in FIG. 1, the control terminals 5 protrude from the sealing body 3 to the z1 side in the z direction.

The plurality of control terminals 5 include a first gate terminal 51A and a second gate terminal 51B. The first gate terminal 51A is electrically connected to the gate electrodes of the first semiconductor elements 2A. The second gate terminal 51B is electrically connected to the gate electrodes of the second semiconductor elements 2B. Other control terminals 5 are used, for example, as a source sense terminal, a temperature monitoring terminal, a current monitoring terminal, or a voltage monitoring terminal, as appropriate.

FIG. 24 shows the circuit configuration of the semiconductor device A30. As with the semiconductor device A30, the semiconductor device A10 has a half-bridge circuit that includes an upper arm circuit 81 and a lower arm circuit 82. The upper arm circuit 81 is constituted of the first region 12A and the plurality of first semiconductor elements 2A electrically bonded to the region. The first semiconductor elements 2A are connected in parallel between the first power supply terminal 41 and the output terminal 43. The gate electrodes of the first semiconductor elements 2A in the upper arm circuit 81 are connected in parallel to the first gate terminal 51A. The first semiconductor elements 2A in the upper arm circuit 83 are driven simultaneously by applying a gate voltage to the first gate terminal 51A using a drive circuit, such as a gate driver, disposed outside the semiconductor device A30.

The lower arm circuit 82 is constituted of the second region 12B and the plurality of second semiconductor elements 2B electrically bonded to the region. The second semiconductor elements 2B are connected in parallel between the output terminal 43 and the second power supply terminal 42. The gate electrodes of the second semiconductor elements 2B in the lower arm circuit 82 are connected in parallel to the second gate terminal 51B. The second semiconductor elements 2B in the lower arm circuit 82 are driven simultaneously by applying a gate voltage to the second gate terminal 51B using a drive circuit, such as a gate driver, disposed outside the semiconductor device A30.

The present embodiment also suppresses the leakage of the material interposed between the first surface 111 and the installation surface. As understood from present embodiment, the specific configuration of the semiconductor device configured as a power module according to the present disclosure is not limited in any way.

### Fourth Embodiment

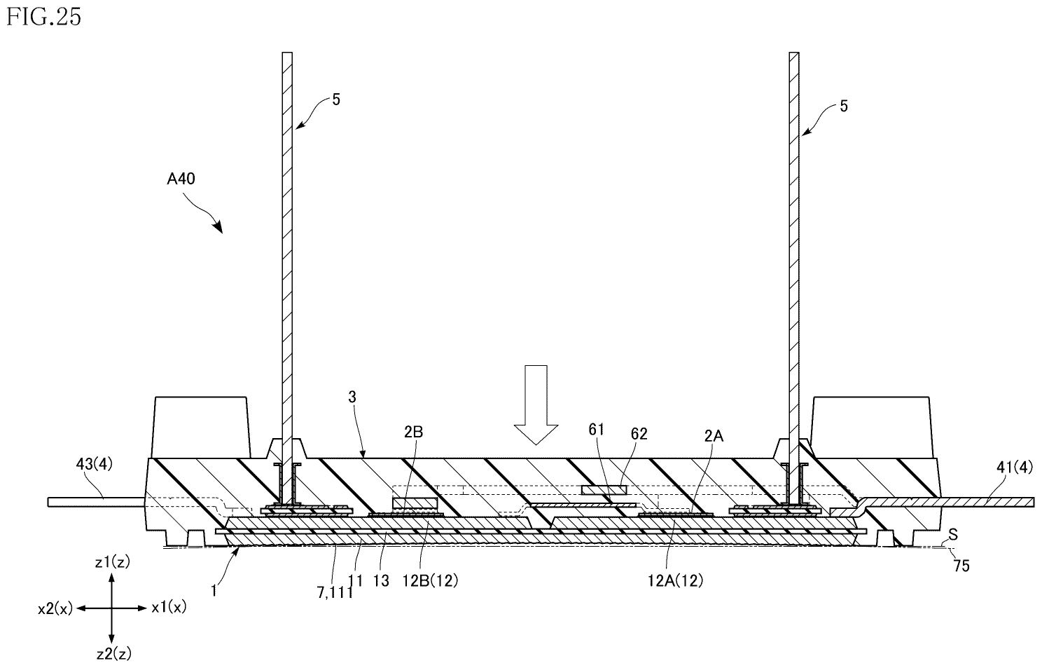

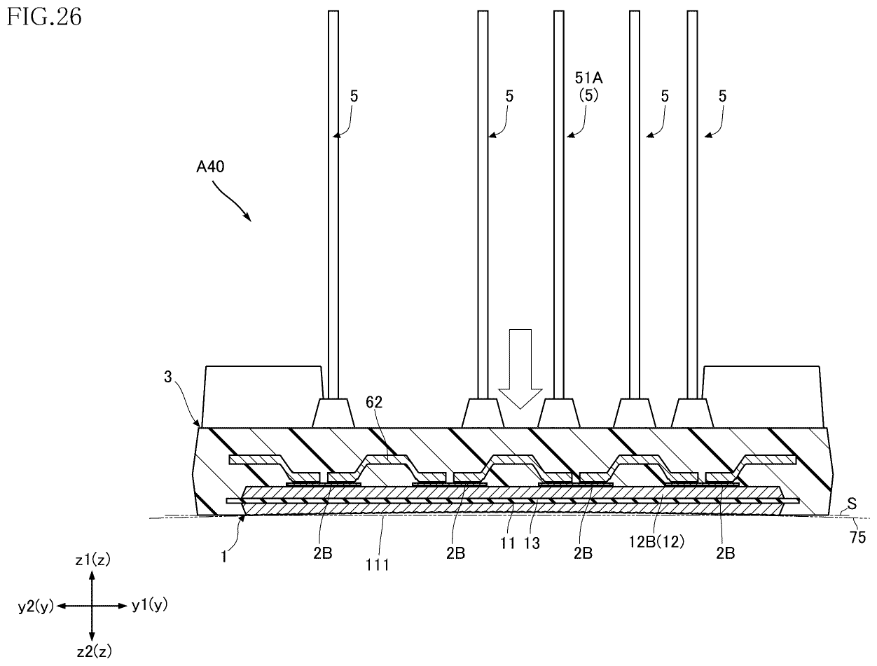

FIGS. 25 and 26 show a semiconductor device according to a fourth embodiment of the present disclosure. In the semiconductor device A40 of the present embodiment, the average line 75 of the uneven region 7 in the first surface 111 is concave toward the z1 side in the thickness direction z. The size of the concave shape of the uneven region 7 as viewed in the thickness direction z is not limited in any way. For example, the size of the concave shape as viewed in the thickness direction z is set to ⅓ or more of the size of the first surface 111 in the short-side direction.

The uneven region 7, of which average line 75 is concave toward the z2 side in the thickness direction z, can be formed, for example, by setting the irradiation power or irradiation time of the pulsed laser L for forming the recesses 71 to be larger or longer at a location closer to the center of the first surface 111 and smaller or shorter at a location farther from the center.

The present embodiment also suppresses the leakage of the material interposed between the first surface 111 and the installation surface. As shown in FIGS. 25 and 26, the semiconductor device A40 is installed on the installation surface S by pressing the central portion on the z1 side in the thickness direction z of the sealing body 3, for example. Because of the shape of the average line 75 of the uneven region 7 that is concave toward the z1 side in the thickness direction z2, the four corners of the first surface 111 first come into contact with the installation surface S during the installation process. At that time, the central portion of the first surface 111 is relatively spaced apart from the installation surface S. When the force pressing the sealing body 3 is subsequently increased, the central portion of the first metal layer 11 are brought closer to the installation surface S. Thus, the entirety of the first surface 111 can be reliably brought into contact with or closer to the installation surface S.

The semiconductor device and the method for manufacturing the semiconductor device according to the present disclosure is not limited to the above-described embodiments. Various modifications in design may be made freely in the specific configuration of the semiconductor device and the method for manufacturing the semiconductor device according to the present disclosure. The present disclosure includes embodiments described in the following clauses.

### Clause 1

A semiconductor device comprising:
a support;
a semiconductor element disposed on a first side in a thickness direction of the support; and
a sealing body covering a part of the support and the semiconductor element, wherein
the support includes a first surface facing a second side in the thickness direction and exposed from the sealing body, and
the first surface includes an uneven region comprising a plurality of dot-shaped recesses overlapping with each other.

### Clause 2

The semiconductor device according to clause 1, wherein the plurality of recess are arranged along a plurality of arrangement lines.

### Clause 3

The semiconductor device according to clause 2, wherein the plurality of arrangement lines include a plurality of curves having different radii of curvature.

### Clause 4

The semiconductor device according to clause 3, wherein the plurality of arrangement lines are arranged concentrically.

### Clause 5

The semiconductor device according to clause 4, wherein the plurality of arrangement lines form a circle or an ellipse.

### Clause 6

The semiconductor device according to any one of clauses 2 to 5, wherein the plurality of arrangement line include a straight arrangement line.

### Clause 7

The semiconductor device according to clause 6, wherein the first surface has a shape elongated in a first direction orthogonal to the thickness direction, and
the plurality of arrangement lines include a straight arrangement line along a second direction orthogonal to the thickness direction and the first direction.

### Clause 8

The semiconductor device according to any one of clauses 1 to 7, wherein the uneven region is provided entirely on the first surface.

### Clause 9

The semiconductor device according to any one of clauses 1 to 8, wherein the uneven region has an average line that is concave toward the first side or bulges to the second side in the thickness direction.

### Clause 10

The semiconductor device according to any one of clauses 1 to 9, wherein the support includes a first metal layer that provides the first surface.

### Clause 11

The semiconductor device according to clause 10, wherein the first metal layer is mainly composed of Cu.

### Clause 12

The semiconductor device according to clause 11, wherein the support includes an insulating layer disposed on the first side in the thickness direction with respect to the first metal layer.

### Clause 13

The semiconductor device according to clause 12, wherein the support includes a second metal layer disposed on the first side in the thickness direction with respect to the insulating layer.

### Clause 14

The semiconductor device according to clause 13, wherein the semiconductor element is mounted on the second metal layer.

### Clause 15

The semiconductor device according to clause 14, comprising a plurality of said semiconductor elements, wherein
the second metal layer includes a first region and a second region spaced apart from each other in a direction orthogonal to the thickness direction, and
the plurality of semiconductor elements include a first semiconductor element mounted on the first region and a second semiconductor element mounted on the second region.

### Clause 16

The semiconductor device according to clause 15, wherein the first semiconductor element and the second semiconductor element are switching elements.

### Clause 17

The semiconductor device according to clause 16, wherein the semiconductor device includes a half-bridge circuit that includes an upper arm circuit constituted by the first semiconductor element and a lower arm circuit constituted by the second semiconductor element.

### Clause 18

A method for manufacturing a semiconductor device, the semiconductor device comprising:
a support;
a semiconductor element disposed on a first side in a thickness direction of the support; and
a sealing body covering a part of the support and the semiconductor element,
the support including a first surface facing a second side in the thickness direction and exposed from the sealing body,
wherein the method comprises forming in the first surface an uneven region comprising a plurality of dot-shaped recesses overlapping with each other by irradiating the first surface with a pulsed laser.

### REFERENCE NUMERALS

A10, A11, A12, A13, A14, A15, A20, A30, A40: Semiconductor device
1: Support 2A: First semiconductor element
2B: Second semiconductor element 3: Sealing body
4: Main current terminal 5: Control terminal
7: Uneven region 11: First metal layer
12: Second metal layer 12A: First region
12B: Second region 13: Insulating layer
13A: First region 13B: Second region
13C: Third region 31: Case
32: Sealing resin 33: Cover
39: Mounting hole 41: First power supply terminal
42: Second power supply terminal 43: Output terminal
51A: First gate terminal 51B: Second gate terminal
61: First conductive member 62: Second conductive member
70: Arrangement line 71: Recess
75: Average line 81: Upper arm circuit
82: Lower arm circuit 111: First surface
115: Support hole 121A: First region
121B: Second region 121C: Third region
122A: First region 122B: Second region
122C: Third region 123A: First region
123B: Second region 123C: Third region
141: Third metal layer 142: Bonding layer
L: Pulsed laser S: Installation surface
x: First direction y: Second direction z: Thickness direction

1. A semiconductor device comprising:
a support;
a semiconductor element disposed on a first side in a thickness direction of the support; and
a sealing body covering a part of the support and the semiconductor element, wherein
the support includes a first surface facing a second side in the thickness direction and exposed from the sealing body, and
the first surface includes an uneven region comprising a plurality of dot-shaped recesses overlapping with each other.

2. The semiconductor device according to claim 1, wherein the plurality of recess are arranged along a plurality of arrangement lines.

3. The semiconductor device according to claim 2, wherein the plurality of arrangement lines include a plurality of curves having different radii of curvature.

4. The semiconductor device according to claim 3, wherein the plurality of arrangement lines are arranged concentrically.

5. The semiconductor device according to claim 4, wherein the plurality of arrangement lines form a circle or an ellipse.

6. The semiconductor device according to claim 2, wherein the plurality of arrangement line include a straight arrangement line.

7. The semiconductor device according to claim 6, wherein the first surface has a shape elongated in a first direction orthogonal to the thickness direction, and
the plurality of arrangement lines include a straight arrangement line along a second direction orthogonal to the thickness direction and the first direction.

8. The semiconductor device according to claim 1, wherein the uneven region is provided entirely on the first surface.

9. The semiconductor device according to claim 1, wherein the uneven region has an average line that is concave toward the first side or bulges to the second side in the thickness direction.

10. The semiconductor device according to claim 1, wherein the support includes a first metal layer that provides the first surface.

11. The semiconductor device according to claim 10, wherein the first metal layer is mainly composed of Cu.

12. The semiconductor device according to claim 11, wherein the support includes an insulating layer disposed on the first side in the thickness direction with respect to the first metal layer.

13. The semiconductor device according to claim 12, wherein the support includes a second metal layer disposed on the first side in the thickness direction with respect to the insulating layer.

14. The semiconductor device according to claim 13, wherein the semiconductor element is mounted on the second metal layer.

15. The semiconductor device according to claim 14, comprising a plurality of said semiconductor elements, wherein
the second metal layer includes a first region and a second region spaced apart from each other in a direction orthogonal to the thickness direction, and
the plurality of semiconductor elements include a first semiconductor element mounted on the first region and a second semiconductor element mounted on the second region.

16. The semiconductor device according to claim 15, wherein the first semiconductor element and the second semiconductor element are switching elements.

17. The semiconductor device according to claim 16, wherein the semiconductor device includes a half-bridge circuit that includes an upper arm circuit constituted by the first semiconductor element and a lower arm circuit constituted by the second semiconductor element.

18. A method for manufacturing a semiconductor device, the semiconductor device comprising:
a support;
a semiconductor element disposed on a first side in a thickness direction of the support; and
a sealing body covering a part of the support and the semiconductor element,
the support including a first surface facing a second side in the thickness direction and exposed from the sealing body,
wherein the method comprises forming in the first surface an uneven region comprising a plurality of dot-shaped recesses overlapping with each other by irradiating the first surface with a pulsed laser.
